(19) United States
(12) Patent Application Publication
(10) Pub. No.: US 2024/0198525 A1
(43) Pub. Date: Jun. 20, 2024

(54) GAS SUPPLY AUTOMATION SYSTEM

(71) Applicant: SEMES CO., LTD., Cheonan-si (KR)

(72) Inventor: Yoon Whoi KIM, Suwon-si (KR)

(73) Assignee: SEMES CO., LTD., Cheonan-si (KR)

(21) Appl. No.: 18/530,863

(22) Filed: Dec. 6, 2023

(30) Foreign Application Priority Data
Dec. 16, 2022 (KR) 10-2022-0176459
Mar. 15, 2023 (KR) 10-2023-0033864

(51) Int. Cl. B25J 9/16; B25J 19/02; H01L 21/67

(52) U.S. Cl. CPC B25J 9/1669; B25J 9/1682; B25J 19/023; H01L 21/67017

(57) ABSTRACT

Embodiments of the inventive concept provide a gas supply automation system for automatically removing a protective cap which is mounted on a valve side of a gas cylinder.

The inventive concept provides gas supply automation system for automatically transferring and supplying a gas cylinder. The gas supply automation system includes a multi-joint robot for gripping and transferring the gas cylinder positioned at a first position to a second position, and taking off a protective cap of the gas cylinder at the second position.

### CROSS-REFERENCE TO RELATED APPLICATIONS

A claim for priority under 35 U.S.C. § 119 is made to Korean Patent Application No. 10-2022-0176459 filed on Dec. 16, 2022 and Korean Patent Application No. 10-2023-0033864 filed on Mar. 15, 2023, in the Korean Intellectual Property Office, the entire contents of which are hereby incorporated by reference.

### BACKGROUND

Embodiments of the inventive concept described herein relate to a gas supply automation system, more specifically, a gas supply automation system for automatically supplying a gas cylinder.

Various process gases such as a cleaning gas and an etching gas are used in a process of manufacturing semiconductors and displays.

These process gases are charged by gas cylinders, and a process gas is supplied to a process equipment by transferring and connecting a gas cylinder to an injection apparatus.

Such a gas cylinder is automatically transferred by a mobile robot because it weighs about 120 kg and is practically difficult for an operator to carry.

In this case, gas cylinders filled with various process gases are equipped with a protective cap on a valve side to which a gas is connected, and such a protective cap cannot supply gas unless removed by the operator.

In particular, since the protective cap is screw-coupled to a neck ring mounted on a top end of the gas cylinder, the protective cap must be rotated to release the screw coupling between the protective cap and the neck ring. Therefore, removing the protective cap by using an automated method was quite cumbersome.

In addition, a conventional gas supply automation system can remove the protective cap while the gas cylinder is fixed in a correct position only if a size of the gas cylinder is within an error range when removing the protective cap.

If the size of the gas cylinder is out of the error range, it is difficult to fix the gas cylinder and remove the protective cap accurately, so a technical solution is also needed to determine whether the size of the gas cylinder is within the error range.

On the other hand, the gas cylinder is input in a cradle unit and then transferred individually to the mobile robot, in which case a recognition code on an information of the process gas is attached to the gas cylinder, and the gas cylinder is read by a code reader to recognize a process gas information contained in the gas cylinder.

Accordingly, regarding the code reader, the recognition code attached to the gas cylinder must be aligned in a certain position to be recognized, but since each gas cylinder input in a cradle unit is not aligned and positioned randomly, a technical solution is needed to align it.

In addition, if the gas cylinder input in a cradle unit is automatically transferred by the mobile robot, a position of the gas cylinder must be placed in a position at which the mobile robot can load, and if the position of the gas cylinder is out of the mobile robot's loading range, the mobile robot cannot load the gas cylinder.

### SUMMARY

Embodiments of the inventive concept provide a gas supply automation system for automatically removing a protective cap which is mounted on a valve side of a gas cylinder.

Embodiments of the inventive concept provide a gas supply automation system for determining whether a size of a gas cylinder is within an error range.

Embodiments of the inventive concept provide a gas supply automation system for easily identifying a recognition code attached to a gas cylinder by a reader by automatically aligning a recognition code position of the gas cylinder.

Embodiments of the inventive concept provide a gas supply automation system for aligning a position of a gas cylinder to a position at which a mobile robot can load.

The technical objectives of the inventive concept are not limited to the above-mentioned ones, and the other unmentioned technical objects will become apparent to those skilled in the art from the following description.

The inventive concept provides a gas supply automation system for automatically transferring and supplying a gas cylinder. The gas supply automation system includes a multi-joint robot for gripping and transferring the gas cylinder positioned at a first position to a second position, and which attaches/detaches a protective cap of the gas cylinder at the second position.

In an embodiment, the gas supply automation system further includes: a cap gripper unit configured to grip the protective cap of the gas cylinder; and a cylinder gripper unit configured to grip a body of the gas cylinder; and wherein the multi-joint robot selectively attaches/detaches the cap gripper unit and the cylinder gripper unit, and grips and attaches/detaches the protective cap of the gas cylinder if the cap gripper unit is mounted, and grips and moves the gas cylinder if the cylinder gripper unit is mounted.

In an embodiment, the gas supply automation system further includes: a tool holder fixing and maintaining the cap gripper unit or the cylinder gripper unit, if the cap gripper unit and the cylinder gripper unit are mounted, and the multi-joint robot selectively attaches/detaches the cap gripper unit and cylinder gripper unit.

In an embodiment, the gas supply automation system further includes: a cap mounting table for forming a mounting region on which the protective cap is mounted, if the cap gripper unit is mounted on the multi-joint robot and the protective cap of the gas cylinder is removed.

In an embodiment, the gas supply automation system further includes: a storage cue for acquiring a process gas information of the gas cylinder and at which a storing region is formed which stores the gas cylinder; a cabinet connected to a gas supply line of a semiconductor equipment, which is mounted with the gas cylinder, and for connecting the gas cylinder to the gas supply line; and a mobile robot for autonomously driving to transfer a gas cylinder having the protective cap removed by the multi-joint robot to the storing region of the storage cue and for autonomously driving to transfer the gas cylinder of the storage cue to the cabinet.

In an embodiment, the gas supply automation system further includes: a size detection unit configured to detect a cylinder region information with respect to a form of the gas cylinder and to detect a case in which the cylinder region information exceeds a predetermined range value.

In an embodiment, the size detection unit includes: a camera unit configured to acquire an image information of the gas cylinder; and a size analysis unit configured to calculate a size value of the gas cylinder within an image information acquired by the camera unit and to detect a cylinder region information with respect to a form of the gas cylinder, and to detect a case in which the cylinder region information exceeds the predetermined range value.

In an embodiment, the camera unit generates a plurality of outer image information with respect to an outer form of the gas cylinder while moving around the gas cylinder in a direction facing a bottom direction of the gas cylinder from a top direction, and the size analysis unit detects a diameter of the gas cylinder from the plurality of outer image information with an outer image information in which an outer form of the gas cylinder is recognized as normal.

In an embodiment, the size analysis unit transmits a non-use cylinder information to the multi-joint robot if a diameter of the gas cylinder which is detected exceeds a predetermined range, and the multi-joint robot grips the gas cylinder to discharge to a side if the non-use cylinder information is input.

In an embodiment, the protective cap is screwed to a neck-ring coupled to a top end of the gas cylinder, and the multi-joint robot releases a screw-coupling between the protective cap and the neck ring by rotating an end when removing the protective cap.

In an embodiment, the gas supply automation system further includes a center detection unit configured to detect a diameter of the gas cylinder by acquiring an image information of the gas cylinder, and which calculates a center coordinate value with respect to the diameter of the gas cylinder which is detected.

In an embodiment, the gas supply automation system further includes: a camera unit configured to be coupled to an end of the multi-joint robot, and wherein the camera unit moves to at least 3 points to generate at least three image information, and wherein the center detection unit calculates a center coordinate value of the gas cylinder via an average value with respect to centers of the gas cylinder from the at least three image information.

In an embodiment, the gas supply automation system further includes an inclination detection unit configured to measure an inclination information of the gas cylinder and to transmit the inclination information to the multi-joint robot, and wherein a rotation axis of the multi-joint robot is corrected by the inclination information if the protective cap of the gas cylinder is gripped and rotated, to rotate in a state which matches a central axis of the gas cylinder.

In an embodiment, the inclination detection unit includes: a distance sensor configured in a number of at least 3, and which is positioned to be spaced part from each other at an end of the multi-joint robot; and an inclination analysis unit configured to connect with the distance sensor to be input with a distance information with respect to at least 3 points measured by each distance sensor, and in which a distance difference with respect to each of the at least 3 points is converted to and set as the inclination information.

The inventive concept provides a gas supply automation system for automatically transferring and supplying a gas cylinder. The gas supply automation system includes a recognition code including a process gas information of the gas cylinder formed at the gas cylinder; and a cylinder inspection unit configured to detect the recognition code so a position of the gas cylinder is changed so a position of the recognition code faces a predetermined direction.

In an embodiment, the gas cylinder is further coupled to the recognition code, and the cylinder inspection unit includes: a code position acquisition unit configured to detect a coupling position information of the recognition code; a rotating table unit configured to rotate the gas cylinder; and a cylinder position control unit configured to be input with the coupling position information of the recognition code and which rotates the rotating table unit so the coupling position information is positioned at a predetermined designated position.

In an embodiment, the cylinder inspection unit further includes an inspection gripping unit configured to grip the gas cylinder, and wherein the cylinder position control unit is configured to adjust a coupling position of the inspection gripping unit to adjust the position of the gas cylinder.

In an embodiment, the inspection gripping unit further includes: a pressurization unit configured to closely contact a side of the gas cylinder; and a position adjusting unit configured to be positioned to face the pressurization unit, to closely contact another side of the gas cylinder, and to pressurize the gas cylinder toward the pressurization unit to change the position of the gas cylinder.

In an embodiment, the cylinder inspection unit further includes: a lift unit configured to lift and lower the gas cylinder by lifting and lowering the gripping unit coupled with the gripping unit, and wherein the cylinder position control unit lifts the gas cylinder by lifting the lifting unit in a state in which the inspection gripping unit grips the gas cylinder, and changes a position so a loading unit of the mobile robot may be inserted into an insertion region of the rotating table unit.

In an embodiment, A gas supply automation system for automatically transferring and supplying a gas cylinder, the gas cylinder having a recognition code including a process gas information of the gas cylinder and at which a protective cap for protecting a valve is screw-coupled to a neck ring at a top thereof, the gas supply automation system comprising: a cap gripper unit configured to grip the protective cap of the gas cylinder; a cylinder gripper unit configured to grip a body of the gas cylinder; a multi-joint robot which selectively attaches/detaches the cap gripper unit and the cylinder gripper unit, and which an end rotates to release a screw-coupling between the protective cap and the neck ring if the cap gripper unit is mounted, and which grips and moves the gas cylinder if the cylinder gripper unit is mounted; a tool holder fixing and maintaining the cap gripper unit or the cylinder gripper unit, if the cap gripper unit and the cylinder gripper unit are mounted, and the multi-joint robot selectively attaches/detaches the cap gripper unit and cylinder gripper unit; a cap mounting table for forming a mounting region on which the protective cap is mounted, if the cap gripper unit is mounted on the multi-joint robot and the protective cap of the gas cylinder is removed, a storage cue for acquiring a process gas information of the gas cylinder and at which a storing region is formed which stores the gas cylinder; a cabinet connected to a gas supply line of a semiconductor equipment, which is mounted with the gas cylinder, and for connecting the gas cylinder to the gas supply line; a mobile robot for autonomously driving to transfer a gas cylinder having a protective cap removed by the multi-joint robot to the storing region of the storage cue and for autonomously driving to transfer the gas cylinder of the storage cue to the cabinet, a size detection unit including a camera unit configured to generate a plurality of outer image information with respect to an outer form of the gas cylinder while moving around gas cylinder while facing a bottom direction from a top; and a size analysis unit configured to calculate a size value of the gas cylinder within an image information acquired by the camera unit and to detect a cylinder region information with respect to a form of the gas cylinder, to detect a case in which the cylinder region information is greater than a predetermined range value, and to detect a diameter of the gas cylinder with an outer image information in which the outer form of the gas cylinder is recognized as normal among the plurality of outer image information; a center detection unit configured to detect the diameter of the gas cylinder by acquiring an image information of the gas cylinder, and which calculates a center coordinate value with respect to the diameter of the gas cylinder which is detected, an inclination detection unit including a distance sensor configured in a plurality of more three or more and which are positioned spaced apart from each other at an end of the multi-joint robot, and an inclination analysis unit configured to communicate with the distance sensor to be input with a distance information with respect to at least three points measured by each distance sensor and which converts a distance difference with respect to the at least three points which are input to set the inclination information; and a cylinder inspection unit including a code position acquisition unit configured to detect a coupling position information of the recognition code; a rotating table unit configured to rotate the gas cylinder; an inspection gripping unit configured to grip the gas cylinder; a lift unit configured to lift and lower the gas cylinder by lifting and lowering the gripping unit by coupling with the gripping unit, and a cylinder position control unit configured to be input with the coupling position information of the recognition code by adjusting a coupling position of the inspection gripping unit to adjust a position of the gas cylinder, to lift the gas cylinder by lifting the lift unit in a state in which the gas cylinder is gripped by the inspection gripping unit, to change a position so a loading unit of the mobile unit may be inserted into an insertion region of the rotating table unit, and to rotate the rotating table unit so the coupling position information is positioned at a predetermined designated position, wherein the size analysis unit transmits the non-use cylinder information to the multi-joint robot if a diameter of a gas cylinder which is detected exceeds a predetermined range, and if the multi-joint robot is input with the non-use cylinder information the gas cylinder is gripped and discharged to a side, the camera unit couples to an end of the multi-joint robot and moves to at least three points and generates at least three image information, the center detection unit calculates a center coordination value of the gas cylinder through an average value of centers of the gas cylinder from the at least three image information, and the multi-joint robot rotates in a state matching a central axis of the gas cylinder by a rotation axis being corrected by the inclination information in a case in which the protective cap of the gas cylinder is gripped and rotated.

According to an embodiment of the inventive concept, a protective cap mounted on a valve side of a gas cylinder may be automatically removed.

According to an embodiment of the inventive concept, whether a size of a gas cylinder is within an error range may be determined.

According to an embodiment of the inventive concept, a recognition code position of a gas cylinder can be automatically aligned to easily identify a recognition code attached to the gas cylinder by a reader.

According to an embodiment of the inventive concept, a position of a gas cylinder may be aligned to a position at which a mobile robot can load.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a block diagram of a gas supply automation system according to an embodiment of the inventive concept when viewed from a perspective direction.

FIG. 2 is an enlarged partial perspective view of a region at which a multi-joint robot shown in FIG. 1 is positioned.

FIG. 3 is a partial plan view of the region at which the multi-joint robot shown in FIG. 2 is positioned.

FIG. 4 is a partial side view illustrating a driving in which the multi-joint robot shown in FIG. 2 inputs a gas cylinder to a cylinder inspection unit.

FIG. 5 is a partial side view of a tool holder shown in FIG. 2.

FIG. 6 is a partial side view of a state in which the multi-joint robot is positioned above a protective cap to remove the protective cap of the gas cylinder shown in FIG. 4.

FIG. 7 is a partial side view of a state in which the multi-joint robot removes the protective cap of the gas cylinder shown in FIG. 6.

FIG. 8 is a partial side view of a state in which the multi-joint robot is positioned on a top portion of the gas cylinder to fasten the protective cap of the gas cylinder.

FIG. 9 is a partial side view of a state in which the multi-joint robot shown in FIG. 8 fastens the protective cap to a neck ring of the gas cylinder.

FIG. 10 shows an image information in a state in which a camera unit attached to the multi-joint robot images the gas cylinder in each of four directions.

FIG. 11 is a partial front view of the cylinder inspection unit shown in FIG. 4.

FIG. 12 is a partial front view of a state in which the cylinder inspection unit shown in FIG. 11 is driven.

FIG. 13 is a driving flowchart for a gas cylinder input method using the gas supply automation system according to an embodiment of the inventive concept.

FIG. 14 is a driving flowchart of a gas cylinder discharge method using the gas supply automation system according to an embodiment of the inventive concept.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

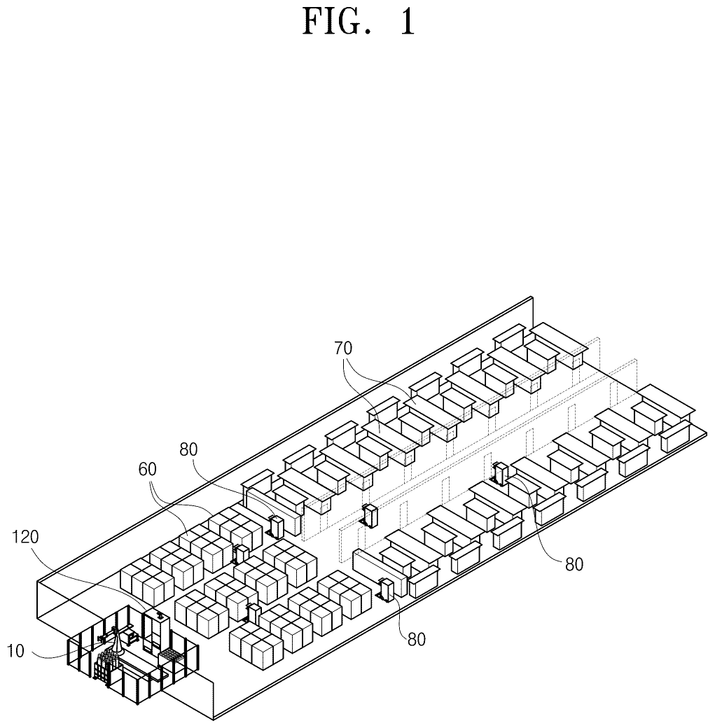

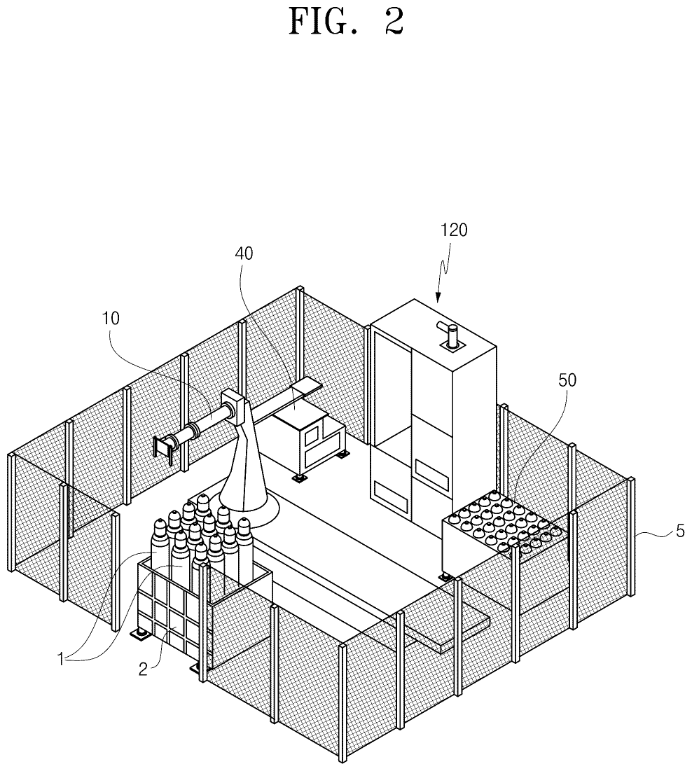

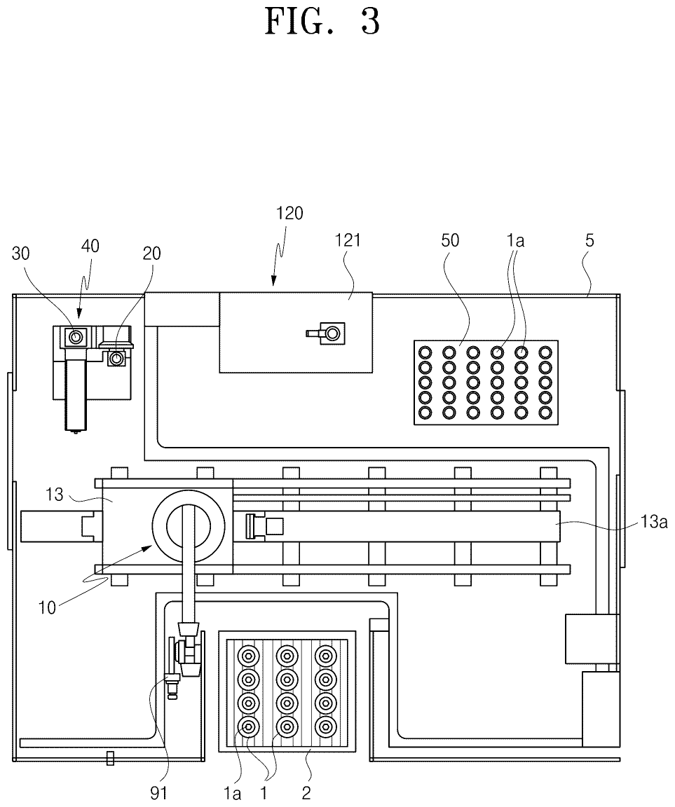

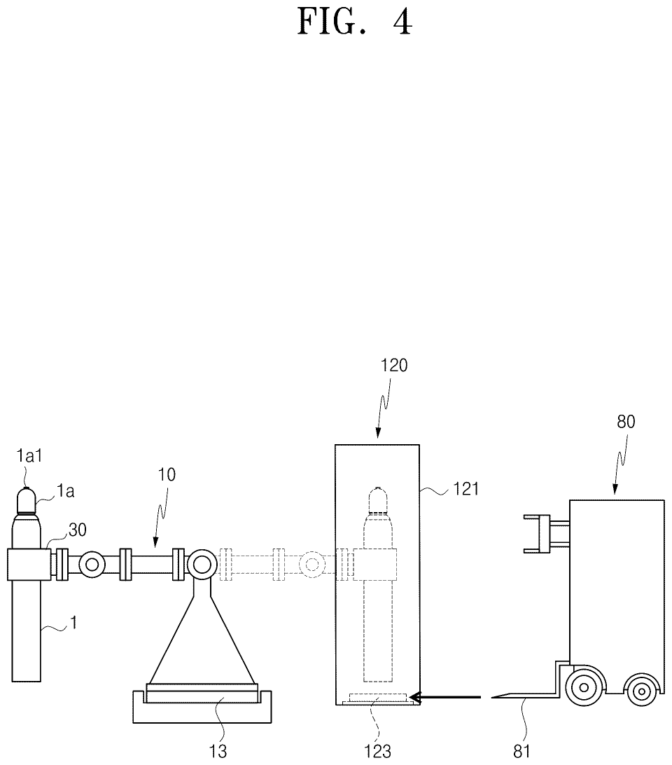

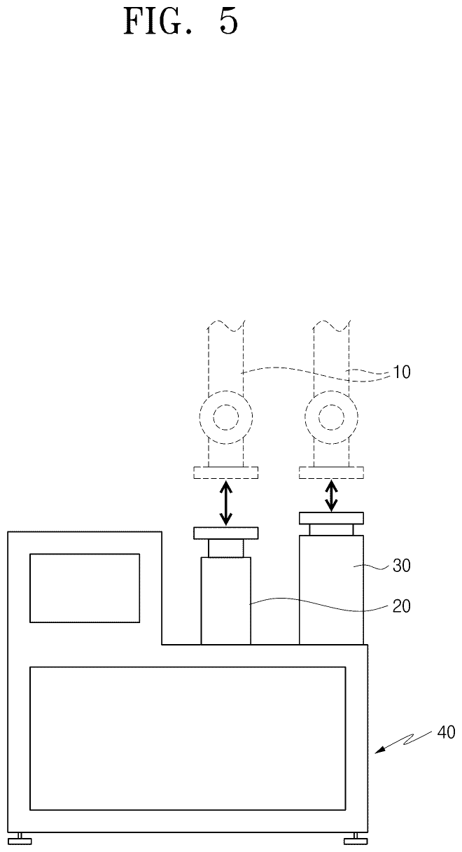

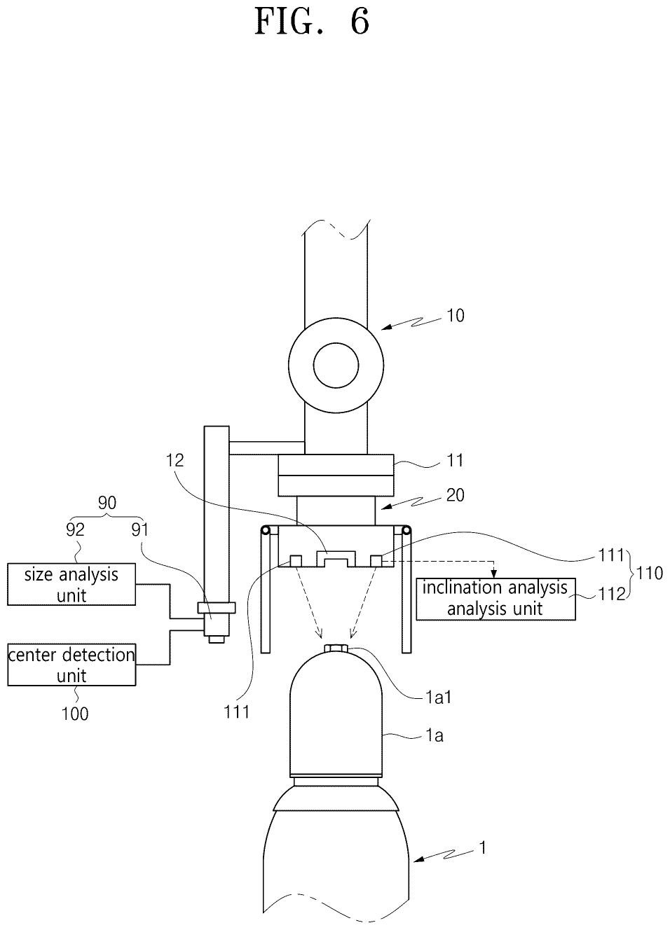

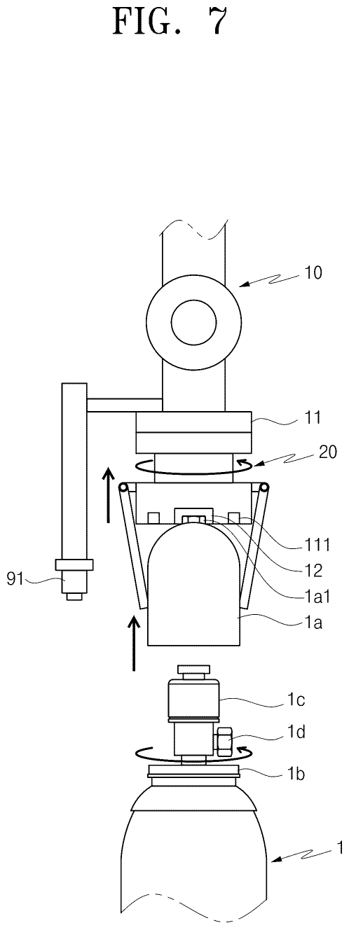

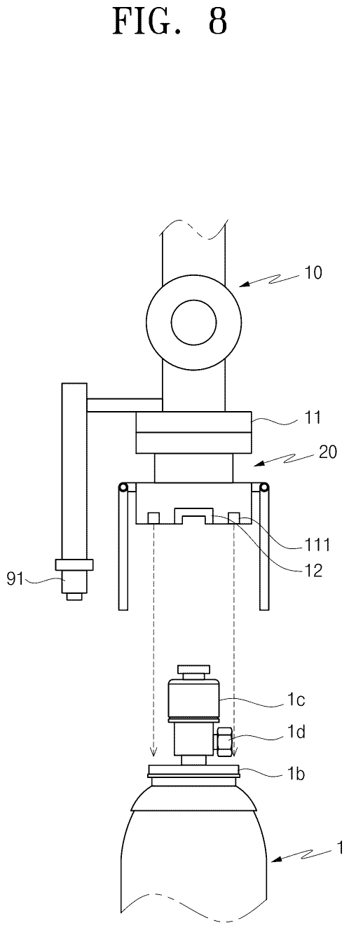

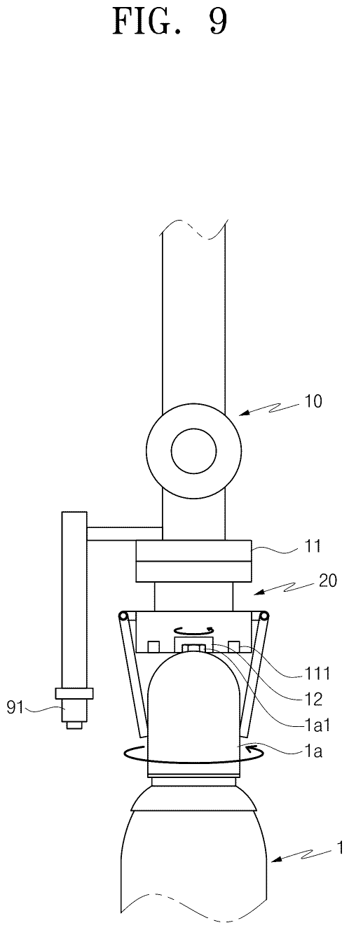

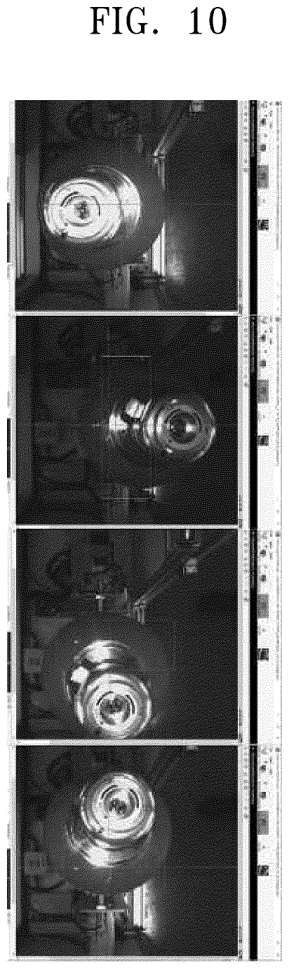

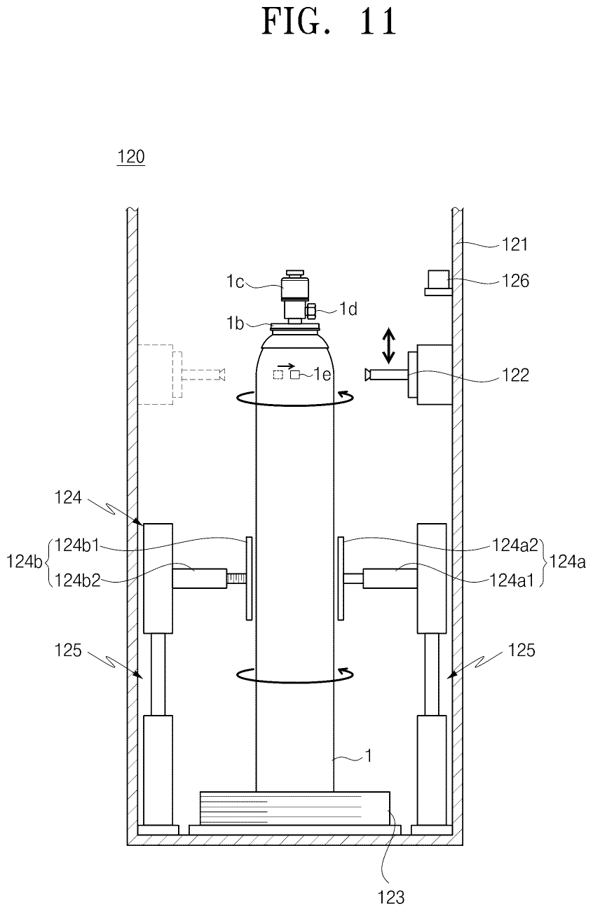

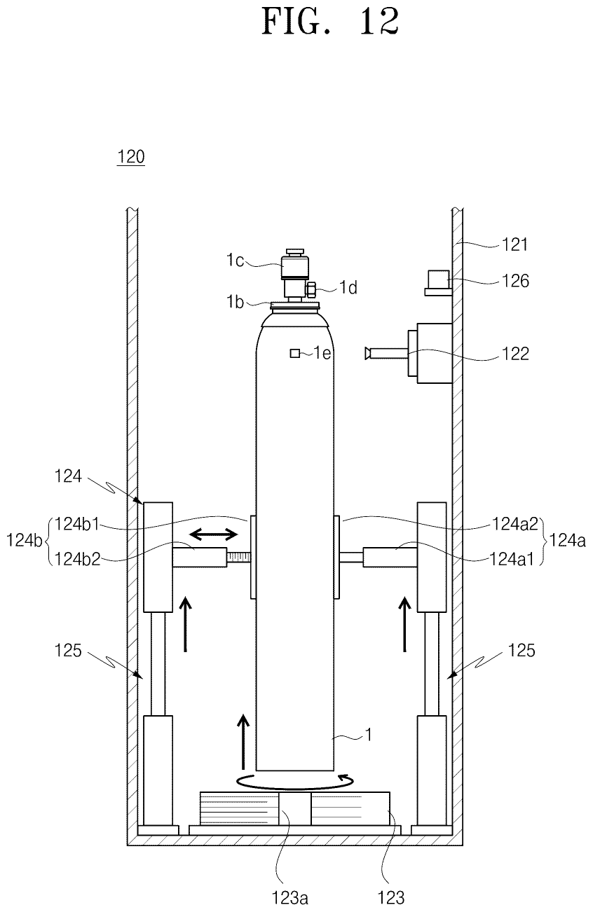

FIG. 1 is a block diagram of a gas supply automation system according to an embodiment of the inventive concept when viewed from a perspective direction. FIG. 2 is an enlarged partial perspective view of a region at which a multi-joint robot shown in FIG. 1 is positioned. FIG. 3 is a partial plan view of the region at which the multi-joint robot shown in FIG. 2 is positioned. FIG. 4 is a partial side view illustrating a driving in which the multi-joint robot shown in FIG. 2 inputs a gas cylinder to a cylinder inspection unit. FIG. 5 is a partial side view of a tool holder shown in FIG. 2. FIG. 6 is a partial side view of a state in which the multi-joint robot is positioned above a protective cap to remove the protective cap of the gas cylinder shown in FIG. 4. FIG. 7 is a partial side view of a state in which the multi-joint robot removes the protective cap of the gas cylinder shown in FIG. 6. FIG. 8 is a partial side view of a state in which the multi-joint robot is positioned on a top portion of the gas cylinder to fasten the protective cap of the gas cylinder. FIG. 9 is a partial side view of a state in which the multi-joint robot shown in FIG. 8 fastens the protective cap to a neck ring of the gas cylinder. FIG. 10 shows an image information in a state in which a camera unit attached to the multi-joint robot images the gas cylinder in each of four directions. FIG. 11 is a partial front view of the cylinder inspection unit shown in FIG. 4. FIG. 12 is a partial front view of a state in which the cylinder inspection unit shown in FIG. 11 is driven.

As described in FIG. 1 to FIG. 12, the gas supply automation system according to an embodiment of the inventive concept includes a multi-joint robot 10, a cap gripper unit 20, a cylinder gripper unit 30, a tool holder 40, a cap mounting table 50, a storage queue 60, a cabinet 70, a mobile robot 80, a size detection unit 90, a center detection unit 100, an inclination detection unit 110, and a cylinder inspection unit 120.

The multi-joint robot 10 is a six-degree-of-freedom robot 6 and transfers the gas cylinder 1. For example, the multi-joint robot 10 can transfer the gas cylinder 1 to a second position in which the cylinder inspection unit 120 is positioned in a state of gripping the gas cylinder 1 in a first position at which the cradle 2 is positioned while the cylinder gripper unit 30 is mounted on an end of the cylinder. In addition, the multi-joint robot 10 grips and attaches/detaches a protective cap 1a of the cylinder. For example, a cap gripper unit 20 is mounted at an end of the multi-joint robot 10 to grip and attaches/detaches the protective cap 1a of the gas cylinder 1 positioned in the second position. In this way, the multi-joint robot 10 can improve a work efficiency by simultaneously implementing a transfer function of the gas cylinder 1 and an attachment/detachment function of the protective cap 1a. In addition, the multi-joint robot 10 may further form a unit attachable/detachable port 11 to selectively couple the cylinder gripper unit 30 and the cap gripper unit 20 to an end thereof. The unit attachable/detachable port 11 may be coupled to a coupling region of each of the cylinder gripper unit 30 and the cap gripper unit 20 by an insertion coupling or a binding coupling, and the like, and the attachable/detachable function between the cylinder gripper unit 30 and the cap gripper unit 20 may be controlled by a robot controller of the multi-joint robot 10. This multi-joint robot 10 can transfer the gas cylinder 1 wherever the gas cylinder 1 is positioned within an operating range, and can remove the protective cap 1a wherever the protective cap 1a is within the operating range. In other words, the multi-joint robot 10 can transfer the gas cylinder 1 and attach/detach the protective cap 1a even if a position of the gas cylinder 1 is not accurately aligned. Accordingly, the multi-joint robot 10 does not follow an algorithm of transferring the gas cylinder 1 and removing the protective cap 1a if the gas cylinder 1 is accurately placed, but is operated by an algorithm which can transfer the gas cylinder 1 and remove the protective cap 1a even if the position of the gas cylinder 1 and the protective cap 1a change every time. That is, in the inventive concept, the multi-joint robot 10 may transfer the gas cylinder 1 even if the position of the gas cylinder 1 is not specified. In this case, the multi-joint robot 10 may grip and transfer the gas cylinder 1 by an algorithm pre-stored in the robot controller, and attach/detach the protective cap 1a. The multi-joint robot 10 is placed in an inlet region at which the gas cylinder 1 is inserted or discharged by cradle 2 unit to transfer the gas cylinder 1 with the protective cap 1a removed to an autonomous driving area at which the mobile robot 80 transfers the gas cylinder 1 by an autonomous driving. In this case, the protective cap 1a may be screw-coupled to a neck ring 1b coupled to a top end of the gas cylinder 1. Accordingly, the protective cap 1a which is screw-coupled to the neck ring 1b protects a valve 1c and a valve inlet 1d unless the screw coupling is released. In this case, if the multi-joint robot 10 removes the protective cap 1a with the cap gripper unit 20, an end rotates to release the screw coupling between the neck ring 1b and the protective cap 1a, and then removes the protective cap 1a. Here, the multi-joint robot 10 is bound to a binder 1a1 of the protective cap 1a if the screw coupling with the protective cap 1a is released, and a nut runner 12 which rotates the protective cap 1a is further configured to rotate the protective cap 1a. Here, the binder 1a1 of the protective cap 1a may be configured in a prismatic shape when viewed toward a plane. For example, the binder 1a1 may be configured in a hexagonal shape and nut-coupled to the nut runner 12. In addition, if the multi-joint robot 10 rotates the protective cap 1a, an angle at which the protective cap 1a is inclined from a center of the protective cap 1a must be corrected to remove the protective cap 1a. Accordingly, the multi-joint robot 10 determines the center and an inclination of the protective cap 1a through the center detection unit 100 and the inclination detection unit 110, and a detailed description thereof will be described later. Meanwhile, a position of the multi-joint robot 10 may be changed. For example, the multi-joint robot 10 may be mounted on a transfer base 13 of a linear motor 13a and its position may be changed depending on a position of the transfer base 13. On the other hand, a safety fence 5 is installed around the multi-joint robot 10 to prevent accidents when the multi-joint robot 10 is moving, and to prevent the mobile robot 80 from entering a region of the multi-joint robot 10.

The cap gripper unit 20 grips the protective cap 1a of the gas cylinder 1. In this case, when gripping the protective cap 1a, the cap gripper unit 20 can grip the protective cap 1a by closely adhering at least two outer surfaces of the protective cap 1a. For example, the cap gripper unit 20 may be configured in a tong shape to grip an outer surface of the protective cap 1a. In addition, the cap gripper unit 20 can be selectively mounted on an end of the multi-joint robot 10 to grip the protective cap 1a of the gas cylinder 1. In addition, the cap gripper unit 20 may be disposed in a fixed state to the tool holder 40. In addition, when the protective cap 1a is removed, the cap gripper unit 20 can rotate while being bound to the binder 1a1 formed on a top portion of the protective cap 1a to release the screw coupling between the protective cap 1a and the neck ring 1b. Here, the binder 1a1 of the protective cap 1a is formed in a hexagonal shape based on a plan view, and a hexagonal groove is formed inside the cap gripper unit 20 to be bound to the binder 1a1 of the protective cap 1a. In this case, the cap gripper unit 20 may rotate the protective cap 1a by rotating the inner hexagonal groove in conjunction with a rotating motor.

The cylinder gripper unit 30 grips a body of the gas cylinder 1. In this case, when gripping the gas cylinder 1, the cylinder gripper unit 30 can grip the gas cylinder 1 by closely adhering at least two or more outer surfaces of the gas cylinder 1. For example, the cylinder gripper unit 30 may be configured in a tong shape to grip the outer surface of the gas cylinder 1. In addition, the cylinder gripper unit 30 may be selectively mounted on an end of the multi-joint robot 10 to grip the gas cylinder 1. In addition, the cylinder gripper unit 30 may be positioned while fixed to the tool holder 40.

The cap gripper unit 20 and the cylinder gripper unit 30 are mounted on the tool holder 40. In this case, the tool holder 40 can fix and maintain the cap gripper unit 20 or the cylinder gripper unit 30 if the multi-joint robot 10 selectively attaches/detaches the cap gripper unit 20 and the cylinder gripper unit 30. For example, if wanting to replace the cap gripper unit 20 mounted on an end of the multi-joint robot 10 with the cylinder gripper unit 30, the tool holder 40 detaches the cap gripper unit 20 coupled to the multi-joint robot 10 while fixed by a tool fixing unit of the tool holder 40, and the cylinder gripper unit 30 may be mounted to the end of the multi-joint robot 10. In addition, if wanting to replace the cylinder gripper unit 30 mounted on the end of the multi-joint robot 10 with the cap gripper unit 20, the tool holder 40 detaches the cylinder gripper unit 30 coupled to the multi-joint robot 10 while fixed by the tool fixing unit of the tool holder 40, and the cap gripper unit 20 may be mounted to the end of the multi-joint robot 10.

The cap mounting table 50 has a mounting region for mounting the protective cap 1a. Here, the mounting region may be formed in the form of a groove on which the protective cap 1a is mounted. The cap mounting table 50 is equipped with a cap gripper unit 20 on the multi-joint robot 10 to remove the protective cap 1a of the gas cylinder 1 and then mounts the removed protective cap 1a in the mounting region. Therefore, the multi-joint robot 10 can store the protective cap 1a collectively by mounting the protective cap 1a on the cap mounting table 50. In addition, if the multi-joint robot 10 couples the protective cap 1a with the gas cylinder 1, the protective cap 1a mounted on the cap mounting table 50 can be gripped by the cap gripper unit 20 and then the gripped protective cap 1a can be coupled with the gas cylinder 1.

The storage queue 60 provides an accommodation region for primarily accommodating a gas cylinder 1 from which the protective cap 1a has been removed. The storage queue 60 may be configured to accommodate a plurality of gas cylinders. In addition, the storage queue 60 may be used to store a gas cylinder 1 filled with a process gas, and may be used to store a gas cylinder 1 in which a use of process gas has been completed. In addition, the storage queue 60 can obtain a process gas information for each gas cylinder 1 by reading a recognition code 1e attached to the gas cylinder 1 with a code reader (not shown) when storing the gas cylinder 1 by the mobile robot 80, and the mobile robot 80 may transmit the process gas information to the mobile robot 80 when transferring the gas cylinder 1.

The cabinet 70 is connected to a gas supply line of a semiconductor equipment. In addition, the cabinet 70 is equipped with a gas cylinder 1 transferred by the mobile robot 80. Such a cabinet 70 supplies the process gas from the gas cylinder 1 to the semiconductor equipment, monitors a remaining amount of the process gas, and transmits a replacement signal for the gas cylinder 1 to a gas management system (not shown) which manages the mobile robot 80 if the remaining amount of the process gas decreases to a predetermined value or below. At this time, the mobile robots 80 operate to replace a gas cylinder 1 having a remaining amount which is less than the predetermined value with a gas cylinder 1 which is fully charged. In addition, the cabinet 70 can automatically fasten the gas cylinder 1 with the gas supply line by driving a fastening device to replace the gas cylinder 1. In addition, the cabinet 70 is equipped with multiple gas cylinders 1 so that when the process gas of any one gas cylinder 1 is the same or below a certain value, the process gas of the other gas cylinder 1 is connected to the gas supply line so that the process gas is continuously supplied. However, in the inventive concept, a function of the cabinet 70 is not limited to the above example, and of course, it can be modified into any form which can supply the process gas to the semiconductor equipment by providing a region to which the gas cylinder is to be mounted.

The mobile robot 80 autonomously drives the gas cylinder 1 with the protective cap 1a removed by the multi-joint robot 10 from the cylinder inspection unit 120 to the storage queue's accommodation region 60, and autonomously drives to transfer the gas cylinder 1 of the storage queue 60 to the cabinet 70. In addition, the mobile robot 80 receives an incoming and an outgoing schedule information on an incoming and outgoing transfer of the gas cylinder 1 in conjunction with the process gas monitoring system (not shown), and transfers the gas cylinder 1 which has consumed the process gas from the cabinet 70 to the storage queue 60. In addition, the mobile robot 80 connects with the transfer robot monitoring unit (not shown) which manages a position information and a status information of the mobile robot 80 through a wireless communication, receives a transfer schedule of the gas cylinder 1 by the transfer robot monitoring unit to autonomously drive while not overlapping with one another by sharing the position information.

The size detection unit 90 detects a cylinder region information on a form of the gas cylinder 1 and detects a case in which the cylinder region information exceeds a preset range value. For example, the size detection unit 90 can detect a case in which a size of the gas cylinder 1 exceeds a predetermined range value, and can detect if a gas cylinder 1 having a size out of standard is input. The size detection unit 90 may be configured in conjunction with the multi-joint robot 10 to be detected if the gas cylinder 1 is initially input.

As an example of the size detection unit 90, the size detection unit 90 may include a camera unit 91 and a size analysis unit 92.

The camera unit 91 images the gas cylinder 1 to obtain an outer periphery image information of the gas cylinder 1. In this case, the camera unit 91 is integrally coupled with a coupling assembly at an end of the multi-joint robot 10, and may be configured to obtain the outer periphery image information of the gas cylinder 1 in any direction. For example, the camera unit 91 can generate a plurality of outer periphery image information on an outer form of the gas cylinder 1 by moving the multi-joint robot 10 around the gas cylinder 1 in a direction of looking at the gas cylinder 1 from a top to a bottom.

The size analysis unit 92 calculates a size value of the gas cylinder 1 within the image information obtained by the camera unit 91, and can detect if the gas cylinder 1 has a size which out of standard through an image analysis. For example, the size analysis unit 92 can detect a diameter of the gas cylinder 1 with an outer image information, in which an outer side form of the gas cylinder 1 is recognized as normal within the plurality of outer image information of the gas cylinder 1 which is input through the camera unit 91. As such, the size analysis unit 92 can detect the diameter of the gas cylinder 1 even if an interference occurs by the valve 1c or other parts by analyzing the outer image information in various directions around the gas cylinder 1. Here, the size analysis unit 92 transmits an unusable cylinder information to the multi-joint robot 10 if the diameter of the detected gas cylinder 1 exceeds a predetermined range. Then, if the multi-joint robot 10 receives the unusable cylinder information, the gas cylinder 1 is gripped and discharged to a side. Therefore, the size analysis unit 92 separates a non-standard gas cylinder 1 among input gas cylinders 1 to prevent abnormalities from occurring when transferring, storing, and fastening the gas cylinder 1.

By acquiring the image information of the gas cylinder 1, the center detection unit 100 detects the diameter of the gas cylinder 1, and calculates a center coordinate value with respect to a detected diameter of the gas cylinder 1, so the multi-joint robot 10 can remove the protective cap 1a based on a center of the protective cap 1a. If a process of determining the center of the protective cap 1a is not carried out as described above, the cap gripper unit 20 may not be able to accurately grip the protective cap 1a, resulting in a problem that the multi-joint robot 10 cannot proceed with a gripping operation.

Here, the center detection unit 100 may use an image information obtained by the camera unit 91 coupled to an end of the multi-joint robot 10 to detect a center of the gas cylinder 1, which is the center of the protective cap 1a. In this case, the camera unit 91 coupled to the multi-joint robot 10 moves to at least three points by a movement of the multi-joint robot 10 to generate at least three image information. For example, the camera unit 91 can generate the image information by imaging from each of the four directions based on the center of the gas cylinder 1 from a top direction of the gas cylinder 1 by the multi-joint robot 10 as shown in the drawing. Therefore, even if the gas cylinder 1 is covered by the valve 1c or the like and so an information for obtaining the center coordinate value cannot be obtained at any one of the plurality of image information, a center coordinate value of the protective cap 1a, the neck ring 1b, or the gas cylinder 1 can be obtained through the remaining image information. At this time, the center detection unit 100 can obtain the center coordinate value of the gas cylinder 1 by analyzing image information using an image treating process and calculating an average value of the centers of the gas cylinder 1 from at least three image information. In this case, the center detection unit 100 may calculate the center coordinate value not only through an outer diameter center of the gas cylinder 1 but also through an outer diameter center of the protective cap 1a or an outer diameter center of the neck ring 1b. Accordingly, the multi-joint robot 10 can accurately determine the center of the protective cap 1a when rotating and removing the protective cap 1a, so that the cap gripper unit 20 can be accurately disposed on both sides of the center of the protective cap 1a when removing the protective cap 1a.

The inclination detection unit 110 measures an inclination information of the gas cylinder 1 and transmits the inclination information to the multi-joint robot 10. When the multi-joint robot 10 removes the protective cap 1a, the inclination detection unit 110 provides the inclination information to the multi-joint robot 10 which allows the protective cap 1a to be removed without a twisting by the cap gripper unit 20 being corrected by an inclination angle of the protective cap 1a when removing the protective cap 1a. Accordingly, the multi-joint robot 10 rotates in a state corrected with the inclination information to match a central axis of the gas cylinder 1 when gripping and rotating the protective cap 1a of the gas cylinder 1. If the multi-joint robot 10 is not corrected by the inclination information and the protective cap 1a is removed, the protective cap 1a is rotated in a twisted state to press the valve 1c, causing cracks in the protective cap 1a and the valve 1c may be damaged too. Also, a thread of the neck ring 1b screw-coupling with the protective cap 1a may be damaged and not fastened.

As an embodiment of such an inclination detection unit 110, the inclination detection unit 110 may include a distance sensor 111 and an inclination analysis unit 112.

The distance sensor 111 is combined with an end of the multi-joint robot 10 to measure the inclination of the protective cap 1a to measure a distance between the multi-joint robot 10 and the protective cap 1a of the gas cylinder 1. Here, the distance sensor 111 may measure a horizontal surface of the binder 1a1 formed in the protective cap 1a when measuring the distance. In this case, the distance sensor 111 may be coupled near an end of the multi-joint robot 10 or may be coupled to the cap gripper unit 20. Such a distance sensor 111 may consist of a sensor for distance measurement such as a lidar sensor, a laser displacement sensor, an eddy current displacement sensor, or an ultrasonic displacement sensor. In addition, at least three distance sensors 111 may be configured to be spaced apart from each other. Here, the distance sensors 111 are arranged horizontally between each other and are arranged in the same direction as an axial direction of an arm removing the protective cap 1a among the arms constituting the multi-joint robots 10. Accordingly, if the axial direction of the end of the multi-joint robot 10 is the same as that of the gas cylinder 1, a distance value between a horizontal surface of the binder 1a1 of the protective cap 1a and the multi-joint robot 10 measured by the distance sensor 111 is the same.

The inclination analysis unit 112 receives a distance information in conjunction with the distance sensor 111 for at least three points measured by each distance sensor 111 and converts a distance difference for each of the three points into the inclination information and sets it. In this case, the multi-joint robot 10 receives the inclination information from the inclination analysis unit 112, and corrects an inclination until an input inclination information matches an axial direction of an end of the multi-joint robot 10 and an axial direction of the gas cylinder 1. If the axial direction of the multi-joint robot 10 and the axial direction of the gas cylinder 1 match, the distance information measured by each of the distance sensors 111 forms a same value. Therefore, the multi-joint robot 10 can attach/detach the protective cap 1a in a state corrected by inclination information when releasing the screw coupling between the protective cap 1a and the neck ring 1b by gripping the protective cap 1a, preventing a situation in which the inclination is twisted and the protective cap 1a cannot be attached/detached.

The cylinder inspection unit 120 is positioned at the second position and mounts the gas cylinder 1 transferred by the multi-joint robot 10. In addition, the cylinder inspection unit 120 detects the recognition code 1e of the gas cylinder 1 input into an inlet side of the storage queue 60 and changes the position of the gas cylinder 1 so that a position of the recognition code 1e faces in a predetermined direction. In this case, the recognition code 1e coupled to the gas cylinder 1 may be coupled to the outer surface of the gas cylinder 1, in which case the recognition code 1e may be formed as a QR code or a barcode, and may include the process gas information of the gas cylinder 1. Here, the recognition code 1e may be read by a code reader (not shown) to check an information on the gas cylinder 1 in each of the storage queue 60, the cabinet 70, and the mobile robot 80.

As an embodiment of such a cylinder inspection unit 120, the cylinder inspection unit 120 includes an inspection chamber 121, a code position acquisition unit 122, a rotating table unit 123, a gripping unit 124, a lift unit 125, and a cylinder position control unit 126.

The inspection chamber 121 is a chamber for inspecting the gas cylinder 1 to be accommodated in the storage queue 60. The gas cylinder 1 transferred by the multi-joint robot 10 is mounted on the inspection chamber 121.

The code position acquisition unit 122 detects a coupling position information of the recognition code 1e through an image analysis or a position analysis. For example, the code position acquisition unit 122 may detect a coupling position information of the recognition code 1e by analyzing an image information imaged using a camera. For example, the code position acquisition unit 122 can identify the recognition code 1e while the camera is configured to image a side of the gas cylinder 1, and can generate and detect the coupling position information of the recognition code 1e in a form of coordinate values when identifying the recognition code 1e. Here, the detected coupling position information of the recognition code 1e is transmitted to the cylinder position control unit 126. In addition, the code position acquisition unit 122 may be disposed and operated in the inspection chamber 121 for inspecting the gas cylinder 1.

The rotating table unit 123 may include a table disposed under the gas cylinder 1 and a rotating drive body (not shown) such as a motor which rotates the table. If the gas cylinder 1 is settled, the rotating table unit 123 rotates by a control of the cylinder position control unit 126 to rotate the gas cylinder 1. At the rotating table unit 123, an insertion region may be further formed in a center of the table, and a loading unit 81 of the mobile robot 80 for loading the gas cylinder 1 may be inserted into an insertion region 123a.

The inspection gripping unit 124 grips and fixes the gas cylinder 1. In addition, the inspection gripping unit 124 adjusts the position of the gas cylinder 1 so that a central axis of the gas cylinder 1 matches a predetermined reference position if an outer diameter of the gas cylinder 1 is formed differently.

Accordingly, the inspection gripping unit 124 may include a pressurizing unit 124a and a position adjusting unit 124b.

The pressurizing unit 124a may be closely attached to a side of the gas cylinder 1 to support a side when fixing the gas cylinder 1. For example, the pressurizing unit 124a may include a first pressurizing body 124a1 closely attached to the side of the gas cylinder 1, and a pneumatic cylinder 124a2 in which a rod is connected to the first pressurizing body 124a1 to pressurize a certain pressure toward the first pressurizing body 124a1. Here, the first pressurizing body 124a1 may be formed in an arc shape to correspond to a partial region of the outer diameter of the gas cylinder 1.

The position adjusting unit 124b is arranged to face the pressurizing unit 124a, adheres closely to the other side of the gas cylinder 1, and pressurizes the gas cylinder 1 toward the pressurizing unit 124a to change the position of the gas cylinder 1. For example, the position adjusting unit 124b may include a second pressurizing body 124b1 which adheres to the other side of the gas cylinder 1 at an opposite position of the pressurizing unit 124a, and a transfer motor 124b2 connected to the second pressurizing body 124ba to pressurize the second pressurizing body 124b1 toward the center of the gas cylinder 1. The position adjusting unit 124b may drive the transfer motor 124b2 by a control signal of the cylinder position control unit 126 so that the first pressurizing body 124a1 pressurizes the gas cylinder 1 so that the central axis of the gas cylinder 1 is positioned at a reference position. Here, the second pressurizing body 124b1 may be formed in an arc shape to correspond to a partial region of the outer diameter of the gas cylinder 1. Therefore, the second pressurizing body 124b1 may prevent the gas cylinder 1 from leaving a region in which the gas cylinder 1 is formed in an arc shape of the first pressurizing body 124a1 and the second pressurizing body 124b1 while not fully in close contact with the gas cylinder 1.

The lift unit 125 is combined with the gripping unit 124 to lift and lower the gripping unit 124 to lift and lower the gas cylinder 1. Such a lift unit 125 can lift and lower the gripping unit 124 by attaching a carrier such as a linear motor or a pneumatic cylinder to the gripping unit 124.

The cylinder position control unit 126 controls the code position acquisition unit 122, the rotating table unit 123, the gripping unit 124, and the lift unit 125 in conjunction with the code position acquisition unit 122, the rotating table unit 123, the gripping unit 124, and the lift unit 125, to adjust a position with respect to the recognition code 1e of the gas cylinder 1 and to smoothly load the gas cylinder 1 to the mobile robot 80 when the mobile robot 80 transfers the gas cylinder 801.

More specifically, if the gas cylinder 1 is transferred into the inspection chamber 121 by the multi-joint robot 10, the cylinder position control unit 126 controls the gripping unit 124 so the gripping unit 124 is driven to grip the gas cylinder 1.

In addition, the cylinder position control unit 126 is input with the coupling position information of the recognition code 1e coupled to the gas cylinder 1 from the code position acquisition unit 122. In this case, the cylinder position control unit 126 rotates the rotating table unit 123 so that the coupling position information is positioned at a predetermined designated position. At this time, the cylinder position control unit 126 can rotate the gas cylinder 1 by the rotating table unit 123 by releasing the adhesion so that the gripping unit 124 does not completely fix the gas cylinder 1. As a result, the gas cylinder 1 may ensure that a direction at which the recognition code 1e is attached is always placed in a certain position and that the direction of the recognition code 1e is always placed in a certain position if transferred by the mobile robot 80.

In addition, the cylinder position control unit 126 controls the inspection gripping unit 124 to adjust a side position of the gas cylinder 1 so that the central axis of the gas cylinder 1 is aligned with a predetermined axis. In this case, the cylinder position control unit 126 drives the lift unit 125 to lift the gas cylinder 1, preventing it from not being controlled to the target position by a friction with the rotating table unit 123 when the gas cylinder 1 moves sideways. Even if the diameter of the gas cylinder 1 is different, the central axis of the gas cylinder 1 is always placed in a certain position, so when the gas cylinder 1 is transferred to the mobile robot 80, the center axis is twisted and the gas cylinder 1 is not loaded and an accident of a deviation is prevented.

In addition, the cylinder position control unit 126 lifts the lift unit 125 to lift the gas cylinder 1 while the inspection gripping unit 124 grips the gas cylinder 1, and changes a position so that the loading unit 81 of the mobile robot 80 can be inserted into the insertion region 123a of the rotating table unit 123. Therefore, if the gas cylinder 1 is loaded, the loading unit 81 of the mobile robot 80 blocks an element which interferes with a loading operation of the mobile robot 80 in advance by ensuring that a position of the rotating table is always in a constant position.

Hereinafter, a method of inputting and discharging the gas cylinder using the gas supply automation system in accordance with an embodiment of the inventive concept as described above will be described.

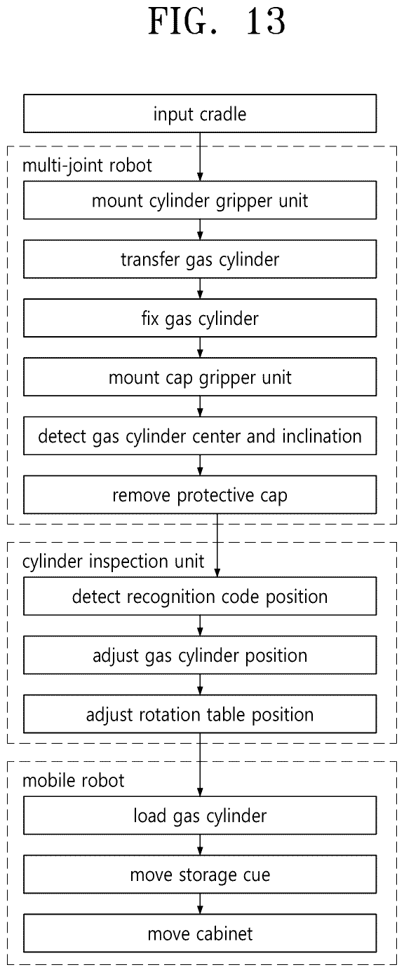

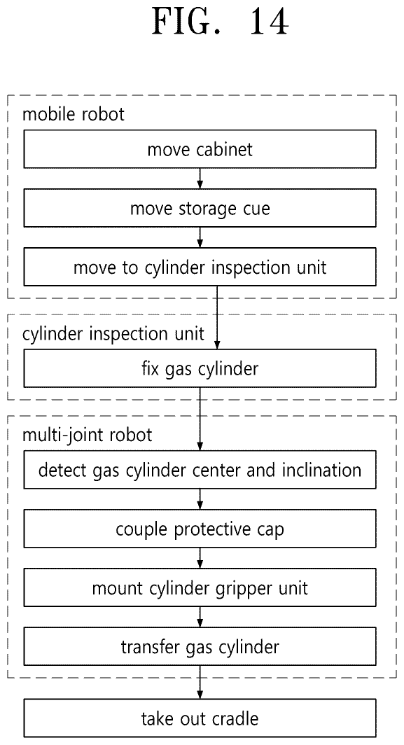

FIG. 13 is a driving flowchart of a gas cylinder input method using a gas supply automation system according to an embodiment of the inventive concept. FIG. 14 is a driving flowchart of a gas cylinder discharge method using a gas supply automation system according to an embodiment of the inventive concept.

In the following description, each of a case of [when the gas cylinder is input] and [when the gas cylinder is discharged] will be described. In this case, since all driving related to the multi-joint robot 10 is carried out by the robot controller's preset algorithm, an explanation of the robot controller's preset algorithm will be omitted, and only an explanation of the operation of the multi-joint robot 10 will be focused on.

### [When the Gas Cylinder is Input]

First, the gas cylinder 1 is positioned within an operating range of the multi-joint robot 10 by transferring the gas cylinders 1 accommodated in cradle 2 units by forklifts, as shown in FIG. 2 and FIG. 3.

Next, the multi-joint robot 10 is moved from the first position at which the cradle 2 is positioned to the tool holder 40, which is the third position, and the cylinder gripper unit 30 is mounted at an end.

Next, the multi-joint robot 10 moves to the cradle 2 in the first position, grips the gas cylinder 1 housed in the cradle 2 with the cylinder gripper unit 30, and transfers the gripped gas cylinder 1 to the cylinder inspection unit 120 in the second position. In this case, the multi-joint robot 10 can receive the central axis and inclination information of the gas cylinder 1 from the center detection unit 100 and the inclination detection unit 110 and transfer the gas cylinder 1 to the cylinder inspection unit 120 even if the position of the gas cylinder 1 is not specified.

Next, the cylinder position control unit 126 of the cylinder inspection unit 120 fixes the gas cylinder 1 by gripping the gas cylinder 1 with an inspection gripping unit 124 as shown in FIG. 11 and FIG. 12.

Next, as is illustrated in FIG. 5, the multi-joint robot 10 moves the end equipped with the cylinder gripper unit 30 to the third position at which the tool holder 40 is positioned, replacing the cylinder gripper unit 30 with the cap gripper unit 20, and moving to the second position at which the cylinder inspection unit 120 is positioned.

Next, as shown in FIG. 6, the multi-joint robot 10 detects the center of the protective cap 1a or the center of the gas cylinder 1. As illustrated above, the multi-joint robot 10 moves in each of the four directions based on the center of the gas cylinder 1 in a top direction of the gas cylinder 1. At this time, the center detection unit 100 acquires the image information for each of the four points through the camera unit 91, and the center detection unit 100 can analyze the image information for each of the four points to detect the center of the protective cap 1a or the center of the gas cylinder 1 within the image information.

Next, in the inclination detection unit 110, a plurality of distance sensors 111 measure the distance information on at least three points of the protective cap 1a or the gas cylinder 1, and the inclination analysis unit 112 analyzes it to generate the inclination information through a distance difference.

Next, the multi-joint robot 10 moves to the center of the protective cap 1a detected by the center detection unit 100, but corrects the inclination information value detected by the inclination detection unit 110 so that the central axis of the cap gripper unit 20 matches the central axis of the protective cap 1a or the gas cylinder 1.

Next, as described in FIG. 7, the multi-joint robot 10 is positioned so that the cap gripper unit 20 is connected to the protective cap 1a, and the screw coupling between the protective cap 1a and the neck ring 1b is released through a rotating function such as a nut runner 12.

Next, the multi-joint robot 10 moves the protective cap 1a to the cap mounting table 50 which is a fourth position while the cap gripper unit 20 grips the protective cap 1a, and settles the protective cap 1a in the mounting region of the cap mounting table 50. In this case, the multi-joint robot 10 may move a certain distance by moving the transfer base 13 while mounted on the transfer base 13 to expand the operating range.

Next, the code position acquisition unit 122 of the cylinder inspection unit 120 detects the center point of the recognition code 1e of the gas cylinder 1 by moving around the gas cylinder 1, as shown in FIG. 11.

The cylinder position control unit 126 receives the coupling position information of the recognition code 1e coupled to the gas cylinder 1 from the code position acquisition unit 122 and rotates the rotating table unit 123 so that the coupling position information is positioned at a predetermined specified position. Then, the gas cylinder 1 is aligned by a rotation of the rotating table unit 123 so that an attachment position of the recognition code 1e is always directed to a certain position.

Next, as shown in FIG. 12, the cylinder position control unit 126 drives the lift unit 125 to lift the gas cylinder 1, and controls the inspection gripping unit 124 to adjust the side position of the gas cylinder 1, so that the central axis of the gas cylinder 1 matches the predetermined axis.

Next, the cylinder position control unit 126 rotates and drives the rotating table unit 123 while the gas cylinder 1 is lifted by the lift unit 125, in which the insertion region 123a of the rotating table unit 123 rotates in a direction in which the loading unit 81 of the mobile robot 80 can be inserted.

Next, the mobile robot 80 autonomously drives according to the transfer schedule of the gas cylinder 1, inserts the loading unit 81 into the insertion region 123a of the rotating table unit 123, loads the gas cylinder 1, and transfers the gas cylinder 1 to the storage queue 60. In this way, the gas cylinder 1 mounted on the storage queue 60 is inserted so that the recognition code 1e is always directed in a certain direction, so that a situation in which the recognition code 1e cannot be read does not occur.

Next, the mobile robot 80 transfers the gas cylinder 1 mounted on the storage queue 60 to the cabinet 70 according to a replacement signal of the gas cylinder 1 of the cabinet 70, and the cabinet 70 is mounted with the gas cylinder 1 transferred by the mobile robot 80 to supply the process gas to the semiconductor facility (not shown).

### [When the Gas Cylinder is Discharged]

First, the cabinet 70 transmits the replacement signal of the gas cylinder 1 which has consumed the process gas to the gas cylinder management system (not shown), and the gas cylinder management system transmits the replacement signal of the gas cylinder 1 which is empty to the mobile robot 80.

Next, the mobile robot 80 transfers and stores the gas cylinder 1 which is empty to the storage queue 60, and transfers the gas cylinder 1 which is empty to the cylinder inspection unit 120 according to a preset schedule.

Next, the cylinder inspection unit 120 fixes the gas cylinder 1 which is empty by gripping it with the inspection gripping unit 124 as shown in FIG. 12.

Next, the multi-joint robot 10 detects the center of the protective cap 1a or the center of the gas cylinder 1 as described above together with FIG. 8. In this case, the multi-joint robot 10 moves in each of four directions from the top direction of the gas cylinder 1 to the center of the gas cylinder 1. At this time, and the center detection unit 100 obtains image information for each of the four points through the camera unit 91.

Next, in the inclination detection unit 110, a plurality of distance sensors 111 measure the distance information on at least three points of the neck ring 1b or the gas cylinder 1, and the inclination analysis unit 112 analyzes it to generate the inclination information through distance differences.

Next, the multi-joint robot 10 then moves a certain distance while mounted on the transfer base 13 while having received the center of the gas cylinder 1 detected by the center detection unit 100 and the inclination information of the gas cylinder 1.

Next, as described in FIG. 9, the multi-joint robot 10 is positioned so that the cap gripper unit 20 is connected to the protective cap 1a, and screws the protective cap 1a and the neck ring 1b through a rotating function such as a nut runner 12.

Next, the multi-joint robot 10 moves the end mounted with the cap gripper unit 20 to the third position at which the tool holder 40 is positioned, replaces the cap gripper unit 20 with the cylinder gripper unit 30, and moves to the second position at which the cylinder inspection unit 120 is positioned.

Next, the multi-joint robot 10 moves a gripped gas cylinder 1 into the cradle 2 after the cylinder gripper unit 30 grips the gas cylinder 1.

When an empty gas cylinder 1 completely fills the inside of the cradle 2 by continuously repeating a discharge process of the gas cylinder 1, the operator uses a forklift to transfer the cradle 2 to an outlet, thereby discharging the empty gas cylinder 1 to the outside.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A gas supply automation system for automatically transferring and supplying a gas cylinder, the gas supply automation system comprising:
a multi-joint robot for gripping and transferring the gas cylinder positioned at a first position to a second position, and which attaches/detaches a protective cap of the gas cylinder at the second position.

2. The gas supply automation system of claim 1, further comprising:
a cap gripper unit configured to grip the protective cap of the gas cylinder; and
a cylinder gripper unit configured to grip a body of the gas cylinder; and
wherein the multi-joint robot selectively attaches/detaches the cap gripper unit and the cylinder gripper unit, and grips and attaches/detaches the protective cap of the gas cylinder if the cap gripper unit is mounted, and grips and moves the gas cylinder if the cylinder gripper unit is mounted.

3. The gas supply automation system of claim 2, further comprising:
a tool holder fixing and maintaining the cap gripper unit or the cylinder gripper unit, if the cap gripper unit and the cylinder gripper unit are mounted, and the multi-joint robot selectively attaches/detaches the cap gripper unit and cylinder gripper unit.

4. The gas supply automation system of claim 2, further comprising:
a cap mounting table for forming a mounting region on which the protective cap is mounted, if the cap gripper unit is mounted on the multi-joint robot and the protective cap of the gas cylinder is removed.

5. The gas supply automation system of claim 4, further comprising:
a storage cue for acquiring a process gas information of the gas cylinder and at which a storing region is formed which stores the gas cylinder;
a cabinet connected to a gas supply line of a semiconductor equipment, which is mounted with the gas cylinder, and for connecting the gas cylinder to the gas supply line; and
a mobile robot for autonomously driving to transfer a gas cylinder having the protective cap removed by the multi-joint robot to the storing region of the storage cue and for autonomously driving to transfer the gas cylinder of the storage cue to the cabinet.

6. The gas supply automation system of claim 1, further comprising:
a size detection unit configured to detect a cylinder region information with respect to a form of the gas cylinder and to detect a case in which the cylinder region information exceeds a predetermined range value.

7. The gas supply automation system of claim 6, wherein the size detection unit includes:
a camera unit configured to acquire an image information of the gas cylinder; and
a size analysis unit configured to calculate a size value of the gas cylinder within an image information acquired by the camera unit and to detect a cylinder region information with respect to a form of the gas cylinder, and to detect a case in which the cylinder region information exceeds the predetermined range value.

8. The gas supply automation system of claim 7, wherein the camera unit generates a plurality of outer image information with respect to an outer form of the gas cylinder while moving around the gas cylinder in a direction facing a bottom direction of the gas cylinder from a top direction, and
the size analysis unit detects a diameter of the gas cylinder from the plurality of outer image information with an outer image information in which an outer form of the gas cylinder is recognized as normal.

9. The gas supply automation system of claim 8, wherein the size analysis unit transmits a non-use cylinder information to the multi-joint robot if a diameter of the gas cylinder which is detected exceeds a predetermined range, and
the multi-joint robot grips the gas cylinder to discharge to a side if the non-use cylinder information is input.

10. The gas supply automation system of claim 1, wherein the protective cap is screwed to a neck-ring coupled to a top end of the gas cylinder, and
the multi-joint robot releases a screw-coupling between the protective cap and the neck ring by rotating an end when removing the protective cap.

11. The gas supply automation system of claim 10, further comprising a center detection unit configured to detect a diameter of the gas cylinder by acquiring an image information of the gas cylinder, and which calculates a center coordinate value with respect to the diameter of the gas cylinder which is detected.

12. The gas supply automation system of claim 11, further comprising:
a camera unit configured to be coupled to an end of the multi-joint robot, and
wherein the camera unit moves to at least 3 points to generate at least three image information, and
wherein the center detection unit calculates a center coordinate value of the gas cylinder via an average value with respect to centers of the gas cylinder from the at least three image information.

13. The gas supply automation system of claim 10, further comprising an inclination detection unit configured to measure an inclination information of the gas cylinder and to transmit the inclination information to the multi-joint robot, and
wherein a rotation axis of the multi-joint robot is corrected by the inclination information if the protective cap of the gas cylinder is gripped and rotated, to rotate in a state which matches a central axis of the gas cylinder.

14. The gas supply automation system of claim 13, wherein the inclination detection unit includes:
a distance sensor configured in a number of at least 3, and which is positioned to be spaced part from each other at an end of the multi-joint robot; and
an inclination analysis unit configured to connect with the distance sensor to be input with a distance information with respect to at least 3 points measured by each distance sensor, and in which a distance difference with respect to each of the at least 3 points is converted to and set as the inclination information.

15. A gas supply automation system for automatically transferring and supplying a gas cylinder, the gas supply automation system comprising:
a recognition code including a process gas information of the gas cylinder formed at the gas cylinder; and
a cylinder inspection unit configured to detect the recognition code so a position of the gas cylinder is changed so a position of the recognition code faces a predetermined direction.

16. The gas supply automation system of claim 15, wherein the gas cylinder is further coupled to the recognition code, and
the cylinder inspection unit includes:
a code position acquisition unit configured to detect a coupling position information of the recognition code;
a rotating table unit configured to rotate the gas cylinder; and
a cylinder position control unit configured to be input with the coupling position information of the recognition code and which rotates the rotating table unit so the coupling position information is positioned at a predetermined designated position.

17. The gas supply automation system of claim 16, wherein the cylinder inspection unit further includes an inspection gripping unit configured to grip the gas cylinder, and
wherein the cylinder position control unit is configured to adjust a coupling position of the inspection gripping unit to adjust the position of the gas cylinder.

18. The gas supply automation system of claim 17, wherein the inspection gripping unit further includes:
a pressurization unit configured to closely contact a side of the gas cylinder; and
a position adjusting unit configured to be positioned to face the pressurization unit, to closely contact another side of the gas cylinder, and to pressurize the gas cylinder toward the pressurization unit to change the position of the gas cylinder.

19. The gas supply automation system of claim 17, wherein the cylinder inspection unit further includes:
a lift unit configured to lift and lower the gas cylinder by lifting and lowering the gripping unit coupled with the gripping unit, and
wherein the cylinder position control unit lifts the gas cylinder by lifting the lifting unit in a state in which the inspection gripping unit grips the gas cylinder, and changes a position so a loading unit of the mobile robot may be inserted into an insertion region of the rotating table unit.

20. A gas supply automation system for automatically transferring and supplying a gas cylinder, the gas cylinder having a recognition code including a process gas information of the gas cylinder and at which a protective cap for protecting a valve is screw-coupled to a neck ring at a top thereof, the gas supply automation system comprising:
a cap gripper unit configured to grip the protective cap of the gas cylinder;
a cylinder gripper unit configured to grip a body of the gas cylinder;
a multi-joint robot which selectively attaches/detaches the cap gripper unit and the cylinder gripper unit, and which an end rotates to release a screw-coupling between the protective cap and the neck ring if the cap gripper unit is mounted, and which grips and moves the gas cylinder if the cylinder gripper unit is mounted;
a tool holder fixing and maintaining the cap gripper unit or the cylinder gripper unit, if the cap gripper unit and the cylinder gripper unit are mounted, and the multi-joint robot selectively attaches/detaches the cap gripper unit and cylinder gripper unit;
a cap mounting table for forming a mounting region on which the protective cap is mounted, if the cap gripper unit is mounted on the multi-joint robot and the protective cap of the gas cylinder is removed;
a storage cue for acquiring a process gas information of the gas cylinder and at which a storing region is formed which stores the gas cylinder;
a cabinet connected to a gas supply line of a semiconductor equipment, which is mounted with the gas cylinder, and for connecting the gas cylinder to the gas supply line;
a mobile robot for autonomously driving to transfer a gas cylinder having a protective cap removed by the multi-joint robot to the storing region of the storage cue and for autonomously driving to transfer the gas cylinder of the storage cue to the cabinet;
a size detection unit including a camera unit configured to generate a plurality of outer image information with respect to an outer form of the gas cylinder while moving around gas cylinder while facing a bottom direction from a top; and a size analysis unit configured to calculate a size value of the gas cylinder within an image information acquired by the camera unit and to detect a cylinder region information with respect to a form of the gas cylinder, to detect a case in which the cylinder region information is greater than a predetermined range value, and to detect a diameter of the gas cylinder with an outer image information in which the outer form of the gas cylinder is recognized as normal among the plurality of outer image information;
a center detection unit configured to detect the diameter of the gas cylinder by acquiring an image information of the gas cylinder, and which calculates a center coordinate value with respect to the diameter of the gas cylinder which is detected;
an inclination detection unit including a distance sensor configured in a plurality of more three or more and which are positioned spaced apart from each other at an end of the multi-joint robot, and an inclination analysis unit configured to communicate with the distance sensor to be input with a distance information with respect to at least three points measured by each distance sensor and which converts a distance difference with respect to the at least three points which are input to set the inclination information; and
a cylinder inspection unit including a code position acquisition unit configured to detect a coupling position information of the recognition code; a rotating table unit configured to rotate the gas cylinder; an inspection gripping unit configured to grip the gas cylinder; a lift unit configured to lift and lower the gas cylinder by lifting and lowering the gripping unit by coupling with the gripping unit, and a cylinder position control unit configured to be input with the coupling position information of the recognition code by adjusting a coupling position of the inspection gripping unit to adjust a position of the gas cylinder, to lift the gas cylinder by lifting the lift unit in a state in which the gas cylinder is gripped by the inspection gripping unit, to change a position so a loading unit of the mobile unit may be inserted into an insertion region of the rotating table unit, and to rotate the rotating table unit so the coupling position information is positioned at a predetermined designated position, and
wherein the size analysis unit transmits the non-use cylinder information to the multi-joint robot if a diameter of a gas cylinder which is detected exceeds a predetermined range, and if the multi-joint robot is input with the non-use cylinder information the gas cylinder is gripped and discharged to a side,
the camera unit couples to an end of the multi-joint robot and moves to at least three points and generates at least three image information,
the center detection unit calculates a center coordination value of the gas cylinder through an average value of centers of the gas cylinder from the at least three image information, and
the multi-joint robot rotates in a state matching a central axis of the gas cylinder by a rotation axis being corrected by the inclination information in a case in which the protective cap of the gas cylinder is gripped and rotated.
